(19) United States
(12) Patent Application Publication
(10) Pub. No.: US 2023/0341436 A1
(43) Pub. Date: Oct. 26, 2023

(54) TEST PROBES AND TEST SOCKET HAVING SAID TEST PROBES

(71) Applicant: Hirose Electric Co., Ltd., Yokohama (JP)

(72) Inventor: Tatsuya ARAI, Yokohama (JP)

(21) Appl. No.: 18/138,586

(22) Filed: Apr. 24, 2023

(30) Foreign Application Priority Data
Apr. 26, 2022 (JP) 2022-072106

(51) Int. Cl. G01R 1/04

(52) U.S. Cl. CPC G01R 1/0441

(57) ABSTRACT

To provide test probes with an increased path for current flow and a test socket having such test probes, involving a support of an electrically conductive material having a first face and a second face, first contact members provided adjacent to the first face of the support, and second contact members provided adjacent to the second face of the support. At least either one of the first contact members or second contact members is provided as a plurality of members, and a plurality of the first contact members and at least one second contact member, or a plurality of the second contact members and at least one first contact member, are electrically connected through the support.

### CROSS-REFERENCE TO RELATED APPLICATIONS

This application claims priority to Japanese Patent Application No. 2022-072106, filed Apr. 26, 2022, the contents of which are incorporated herein by reference in its entirety for all purposes.

### BACKGROUND

### Technical Field

The present invention relates to test probes that can be used for electrical testing of electronic devices, for example, array-based electronic devices such as IC chips obtained by placing a plurality of solder balls, pads, leads, and the like on a package, as well as to a test socket in which a plurality of said test probes are disposed.

### Background Art

An example of conventional test probes and a test socket was disclosed in Patent Document 1 (Japanese Patent Publication No. 5,960,383). It should be noted that the reference numerals used in the discussion hereinbelow follow the reference numerals used in Patent Document 1.

Contacts 3, which serve as test probes, have: a generally cylindrical, hollow, electrically conductive outer casing 31, which is inserted into contact apertures 24 formed in a contact holder 2 serving as a test socket; a resilient member 32 such as a coil spring, and the like, which is disposed within the outer casing 31 and is capable of expanding and contracting in the axial direction of the outer casing 31; an electrically conductive first plunger 33, which is disposed at one end of the coil spring 32 while protruding from one end of the outer casing 31, and is configured in a manner permitting electrical connection to a test apparatus; and an electrically conductive second plunger 34, which is disposed at the other end of the coil spring 32 while protruding from the other end of the outer casing 31, and is electrically connectable to an electronic device. The first plunger 33 and the second plunger are electrically connected to each other through the medium of the outer casing 31 because each of them abuts the outer casing 31 and, additionally, can be electrically connected through the medium of the resilient member 32 by forming the coil spring from an electrically conductive material.

The contact holder 2 can hold the plurality of contacts 3 such that each one extends in the through-thickness direction of the base 51. A guide body 4, which supports said contact holder 2, can be attached to the contact holder 2, and a guide portion or a guide wall 41, which is used to dispose electronic devices to be tested at a predetermined location on the contact holder 2, can be provided in the guide body 4. The guide body 4, while supporting the contact holder 2, can be secured to a printed circuit board or another test apparatus using screw holes 51b and the like.

When testing electronic devices, the contact holder 2 is mounted at a predetermined location of the test apparatus, and an electronic device is disposed at a predetermined location on the contact holder 2 with the help of the guide portion of the guide body 4. Although electric power necessary for testing is normally supplied from the test apparatus to the electronic device through the test probes, in a conventional test probe such as the one disclosed in Patent Document 1, and the like, one outer casing 31 has only one set of plungers provided therein, that is, a first plunger 33 and a second plunger 34, and electrical connection between the first plunger 33 and the second plunger 34 is accomplished through abutment with the outer casing 31 or through the resilient member 32, which is why this current flow path is not particularly large. For this reason, it may not be possible to supply a sufficient amount of electric power necessary for testing, and, in addition, attempting to supply sufficient electric power could lead to a considerable amount of Joule heating being generated in the test probes, and there is therefore a risk that testing could not be properly conducted. To be sure, it should be noted that conductor sections 241 formed in the contact holder 2 of Patent Document 1 on the interior surface of the contact apertures 24 are electrically connected to each other through connection portions 26 that are layered or made up of wiring, as a result of which some of the contacts among the plurality of contacts 3 are electrically connected to the connection portions 26 through the medium of the conductor sections 241. However, the electrical connections through these connection portions 26 are intended merely for compensating for changes in the quality of signal transmission by the contacts 3 and are unrelated to the supply of electric power necessary for testing. In addition, since no current flow path large enough to make such supply possible is provided, the electrical connections through the connection portions 26 do not in any way overcome the shortcomings of the prior art noted above.

### Patent Documents

Patent Document 1: Japanese Patent Publication No. 5,960,383

### SUMMARY

### Problems to be Solved

It is an object of the present invention to provide test probes in which the shortcomings of the prior art noted above are eliminated, as well as a test socket that uses said test probes.

### Technical Solution

To solve the above-mentioned problems, a test probe according to one aspect of the present invention comprises a support of an electrically conductive material having a first face and a second face, first contact members provided adjacent to the first face of the support, and second contact members provided adjacent to the second face of the support, with at least the first contact member or second contact member being provided as a plurality of members; and is characterized by the fact that a plurality of the first contact members and at least one second contact member, or a plurality of the second contact members and at least one first contact member, are electrically connected through the support, and, in addition, a test socket according to one aspect of the present invention has such test probes.

When the test probe, etc., according to this aspect is used, the support itself is formed from an electrically conductive material, as a result of which the plurality of the first contact members and at least one second contact member, or the plurality of the second contact members and at least one first contact member, can be electrically connected through the support. Along with minimizing Joule heating, this makes it possible to increase the value of the electric current flowing through the test probes, and, for that matter, between the first contact members and second contact members, which, for example, makes it possible to supply a sufficient amount of electric power necessary for electronic device testing.

### Technical Effect

According to the present invention, it is possible to provide test probes in which the shortcomings of the prior art noted above are eliminated, as well as a test socket that uses said test probes.

### BRIEF DESCRIPTION OF THE DRAWINGS

FIG. 1 illustrates a schematic perspective view of a test socket according to an exemplary embodiment of the present invention.

FIG. 2 illustrates a partial cross-sectional view of a test probe and a base of a test socket according to an exemplary embodiment of the present invention.

FIG. 3 illustrates a schematic perspective view of a test probe according to an exemplary embodiment of the present invention.

FIG. 4 illustrates a view illustrating a variation of the test probe illustrated in FIG. 3.

FIG. 5 illustrates a view illustrating a variation of the test probe illustrated in FIG. 3.

FIG. 6 illustrates a view illustrating a variation of the test probe illustrated in FIG. 3.

FIG. 7 illustrates a schematic cross-sectional view of the test probe illustrated in FIG. 6.

FIG. 8 illustrates a schematic cross-sectional view of a test probe in which the second contact members themselves are used as resilient members.

FIG. 9 illustrates a schematic cross-sectional view of a test probe in which the second contact members themselves are used as resilient members.

FIG. 10 illustrates a conceptual view of a test probe with added insulation functionality or capacitor functionality.

FIGS. 11A and 11B are views illustrating a support of a test probe with an added insulating layer.

FIGS. 12A and 12B are views illustrating a variation of the support illustrated in FIG. 11A and 11B.

FIG. 13 illustrates a plan view illustrating an exemplary method for arranging test probes in a test socket.

FIGS. 14A and 14B illustrate a plan view illustrating an exemplary method for arranging test probes in a test socket that is capable of achieving a reduction in crosstalk.

FIGS. 15A and 15B illustrate a view illustrating a variation of the present test probe.

### DETAILED DESCRIPTION

Exemplary embodiments for the present invention are described in detail below with reference to drawings. However, the materials, shapes, relative positions of components, and the like described in the embodiments below, except for matters essential to solving the problems of the present invention, are discretionary and can be modified depending on the construction or various conditions of the apparatuses to which the present invention is applied. In addition, unless expressly stated otherwise, the scope of the present invention is not limited to the embodiments specifically described below.

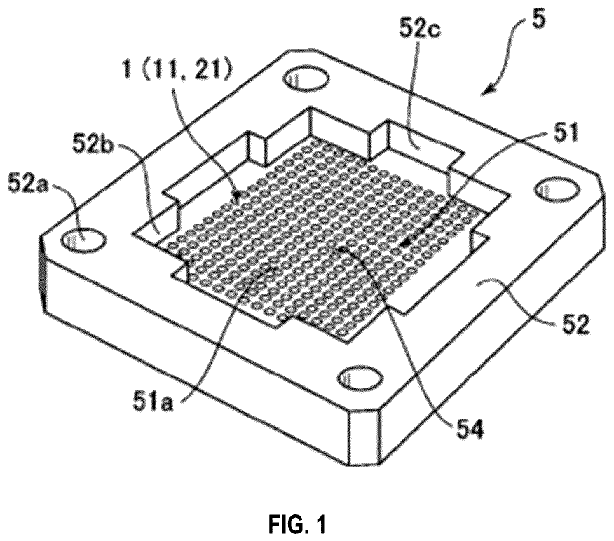

A schematic perspective view of a test socket according to an exemplary embodiment of the present invention is illustrated in FIG. 1. The test socket 5 includes a base 51 made of plastic, in which a plurality of the inventive test probes 1 and other test probes (the hereinafter described test probes 1A, and the like) are provided, and a frame 52 supporting the base 51, which is provided so as to surround the outer periphery of the base 51.

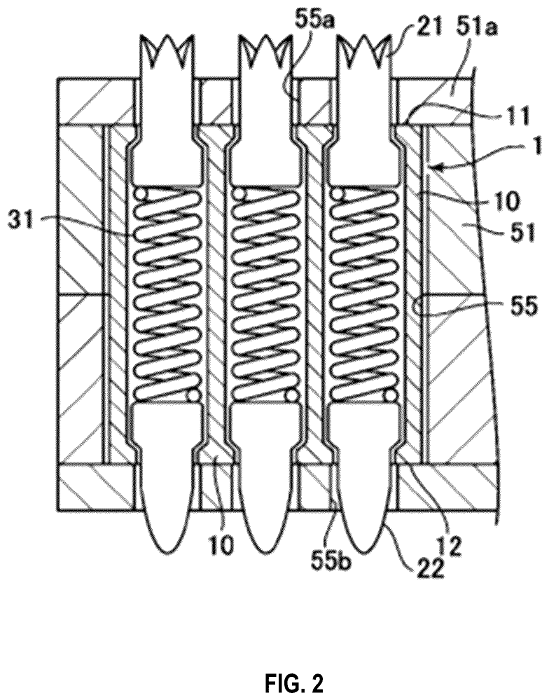

A partial cross-sectional view of the base 51 and the test probes 1 is illustrated in FIG. 2. A plurality of test probes 1 according to an exemplary embodiment of the present invention are installed in a holding space 55 provided in the base 51 so as to extend through the base 51 in the through-thickness direction (vertical direction) of the base 51. The test probes 1 include a support 10, as well as first contact members 21 and second contact members 22. A plurality of first contact members 21 provided adjacent to a first face 11 of these test probes 1, etc., are provided on the surface 51a of the base 51 in a grid-like arrangement, with portions thereof protruding through upper through-holes 55a in the base 51. Similarly, a plurality of second contact members 22 provided adjacent to a second face 12 of these test probes 1, etc., are provided on the backside 51b of the base 51 in a grid-like arrangement, with portions thereof protruding through lower through-holes 55b in the base 51.

The frame 52, which includes a plurality of screw holes 52a, is secured with screws to a printed circuit board or another test apparatus (not shown) using these screw holes 52a. The test socket 5 is mounted at a predetermined location of the test apparatus by securing the frame 52. Once it is mounted at the predetermined location, the second contact members 22 provided adjacent to the second faces 12 of the test probes 1 installed in the base 51 of the test socket 5, i.e., on the side opposite to the first faces 11 in the thickness direction of the base 51, are each electrically connected to predetermined sections of the test apparatus. It should be noted that while the present embodiment has been described on the assumption that the side of the second face 12 is the side opposite to the side of the first face 11 in the thickness direction of the base 51, it does not necessarily have to be provided on the opposite side in the thickness direction, and may be provided, for instance, in the lateral direction, etc., of the base 51 as long as the practice of the present invention is not impaired.

An electronic device to be tested (not shown) is inserted into a concave depressed mounting portion 54 formed by the interior wall surface 52b of the frame 52 and the surface 51a of the base 51. As a result, predetermined sections of the electronic device, for example, predetermined solder balls, and the like, in the IC circuits are electrically connected to individual members in the plurality of the first contact members 21 arranged on the surface 51a of the base 51. A plurality of electronic devices to be tested can be plugged and unplugged from the test socket 5 in turn. In order to facilitate electronic device extraction from the mounting portion 54, indentations 52c for inserting an extraction jig are provided in the interior wall surface 52b of the frame 52.

Electric power necessary for electronic device testing can be supplied, for example, from the test apparatus. Electric current from the test apparatus is supplied to the electronic device through the test probes 1, or more specifically, through electrical connections between the test apparatus and the second contact members 22, between the second contact members 22 and the first contact members 21, and between the first contact members 21 and the electronic device, in that order. As described below, with this configuration, the current flow path is of sufficient size, and the Joule heating thus generated in the test probes 1 in this configuration does not present a problem.

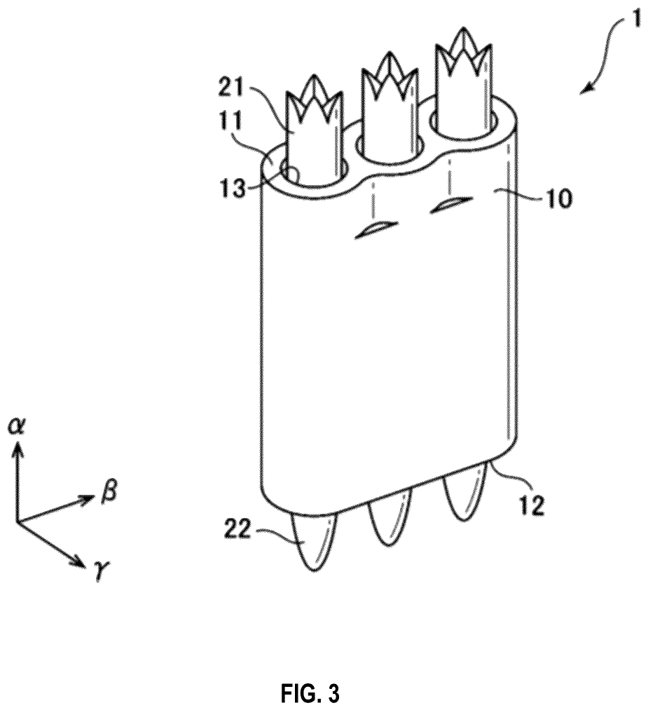

FIG. 3 shows a schematic perspective view of the test probe 1 according to the exemplary embodiment of the present invention illustrated in FIG. 2. As shown in these drawings, the respective shapes of the first contact members 21 and second contact members 22 are not particularly limited and, for example, in a manner similar to the first contact members 21, there may be provided a plurality of sharp embossments or, alternatively, in a manner similar to the second contact members 22, there may be a single mountain-like protrusion. It should be noted that, although in the illustrated example there are three each of the first contact members 21 and second contact members 22, i.e., a total of three pairings of the first contact members 21 and second contact members 22 are provided, as described below, the number of the first contact members 21 and second contact members 22 can be modified as appropriate and is not limited to the above.

While not apparent from the drawings, in a manner similar to the first contact members 21 and second contact members 22, the support 10 consists of an electrically conductive material. The first contact members 21 and second contact members 22 can be manufactured, for example, by stamping and folding a metal plate, while the support 10 can be manufactured, e.g., by machining a block of metal. In a manner similar to the first contact members 21 and second contact members 22, the support 10 is preferably formed from a physically unitary member. However, as long as it is an electrically unitary member, it may be physically formed from a plurality of sections. As used herein, the term “electrically unitary member” refers to a situation in which, for example, a member is physically composed of a plurality of sections, but these sections are in communication with one another, and the member operates as an electrically unitary member with respect to the first contact members 21 and second contact members 22.

The support 10 extends, for example, along the axial direction “a” of the test probe 1, and has its first face 11, where the first contact members 21 are provided, located at one end thereof, and its second face 12, where the second contact members 22 are provided, located at the other end thereof. The first contact members 21 are supported adjacent to the first face 11 and the second contact members 22 are supported adjacent to the second face 12. Although said first contact members 21 and second contact members 22 are supported by the support 10 in a mutually spaced relationship, all of them are electrically connected to the support 10 through abutment with the support 10 and, therefore, are electrically connected to one another through the medium of the support 10. In the test socket 5 illustrated in FIG. 1 and FIG. 2, the support 10 is attached such that the first contact members 21 are each disposed adjacent to the electronic device mounting portion 54 while the second contact members 22 are each disposed adjacent to the test apparatus.

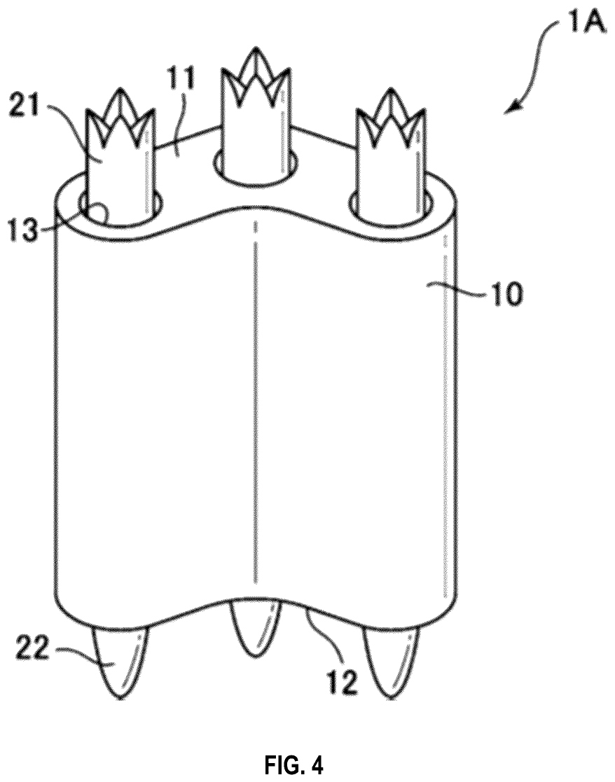

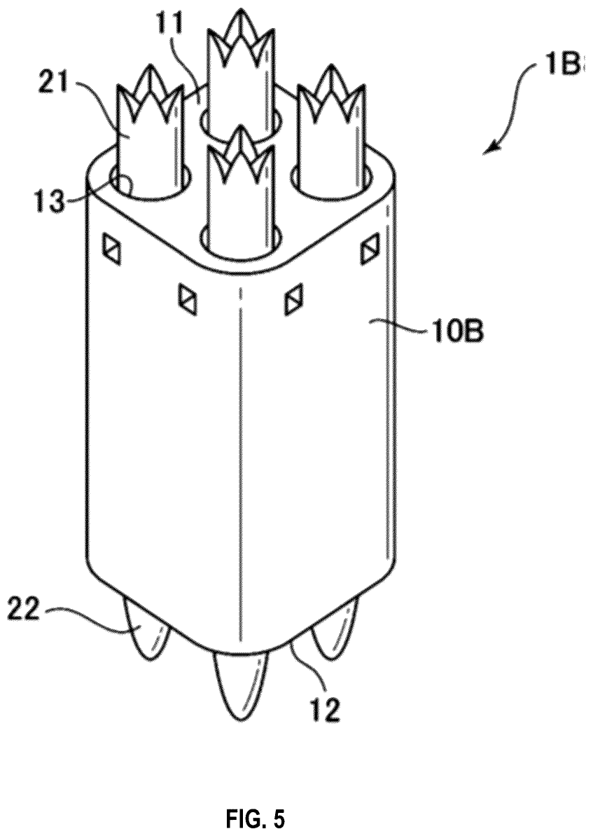

In the cross-sectional direction “β-γ” perpendicular to the axial direction “α”, in other words, on the first face 11 and second face 12 of the support 10, the support 10 is of an integral shape produced by coupling to one another, at their lateral faces, a plurality of test probe elements corresponding to typical conventional test probes. For instance, FIG. 3 shows an example with three test probe elements coupled into a row in the cross-sectional direction “β-γ”. The manner of coupling, however, is not limited thereto. For example, in a manner similar to the test probe 1A illustrated in FIG. 4, three test probe elements may be coupled so as to be orthogonal to one another in the cross-sectional direction “β-γ” and, furthermore, in a manner similar to the test probe 1B illustrated in FIG. 5, four test probe elements may be coupled in a rectangular pattern in the cross-sectional direction “β-γ”. Thus, adopting an integral shape obtained by coupling, to one another, at their lateral faces, a plurality of test probe elements corresponding to typical conventional test probes makes it possible to provide electrically conductive material in the spaces between the paired test probe elements, which makes the electrical capacitance of the support 10 larger than that of a common test probe. As explained above, electric power necessary for electronic device testing is supplied from the test apparatus through the test probes 1, at which time, due to the use of the second contact members 22 electrically connected to the support 10, which has a large electrical capacitance, as well as due to the fact that the second contact members 22 and first contact members 21 are electrically connected through the medium of such a support 10 and, furthermore, due to the use of the first contact members 21 electrically connected to such a support 10, the electrical connections between the test apparatus and the second contact members 22, between the second contact members 22 and the first contact members 21, and between the first contact members 21 and electronic devices, respectively, are accomplished via a larger current flow path, and as a result, along with minimizing Joule heating, it becomes possible to increase the value of the electric current flowing between the first contact members 21 and second contact members 22 and supply a sufficient amount of electric power necessary for testing.

In order to facilitate contact with the electronic device, the first contact members 21 are preferably provided protruding from the first face 11 of the support 10 and, in a similar manner, in order to facilitate contact with the test apparatus, the second contact members 22 are preferably provided protruding from the second face 12 of the support 10. However, as long as the members can be brought into electrical contact with the electronic device or the test apparatus, they do not necessarily have to be provided in a protruding manner and, for instance, if an electronic device or unit being tested has projections, the first contact members 21 or second contact members 22 may be provided retracted into the interior of the support 10 in alignment therewith.

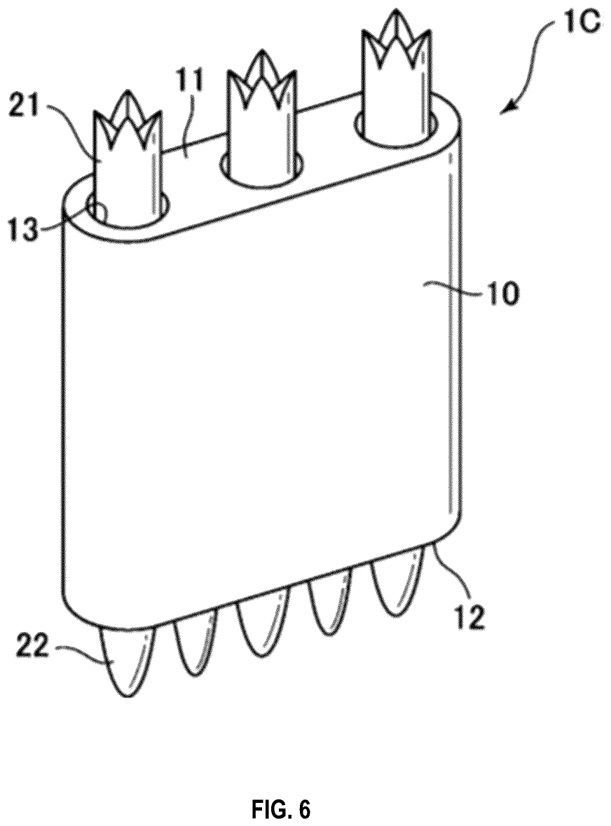

In the present test probe 1, a support 10 formed from an electrically conductive material is used, and at least one of either the first contact member 21 or second contact member 22 is provided as a plurality of members. Providing at least one of the above as a plurality of members allows for a larger current flow path to be created not only for the electrical connections between the second contact member 22 and the first contact member 21, but also for the electrical connections between the test apparatus and the second contact member 22 and/or the electrical connections between the first contact member 21 and the electronic device. It should be noted that it is sufficient for at least either one of the first contact member 21 or second contact member 22 to be provided as a plurality of members, and that the number of members provided is not limited. For example, in a manner similar to the test probe 1 illustrated in FIG. 3 and the test probe 1A illustrated in FIG. 4, the first contact members 21 and second contact members 22, respectively, may be provided in three pairings and, in a manner similar to the test probe 1B illustrated in FIG. 5, the first contact members 21 and second contact members 22, respectively, may be provided in sets of four. Furthermore, in a manner similar to the test probe 1C illustrated in FIG. 6, the first contact members 21 may be provided, for example, in set of three, and the second contact members 22 may be provided, for example, in set of five, and the number of the first contact members 21 and that of the second contact members 22 may be varied. Joule heating can be effectively minimized while supplying a sufficient amount of electric power to the electronic device by making the supply path formed by the second contact members 22 larger than that formed by the first contact members 21 by setting the number of the second contact members 22 provided on the side where the test apparatus is mounted, in other words, for example, the number of the second contact members 22 provided on the side where a high electric current tends to flow easily when electric power is supplied to the electronic device, to a number greater than the number of the first contact members 21 provided adjacent to the electronic device, in a manner similar to the test probe 1C illustrated in FIG. 6.

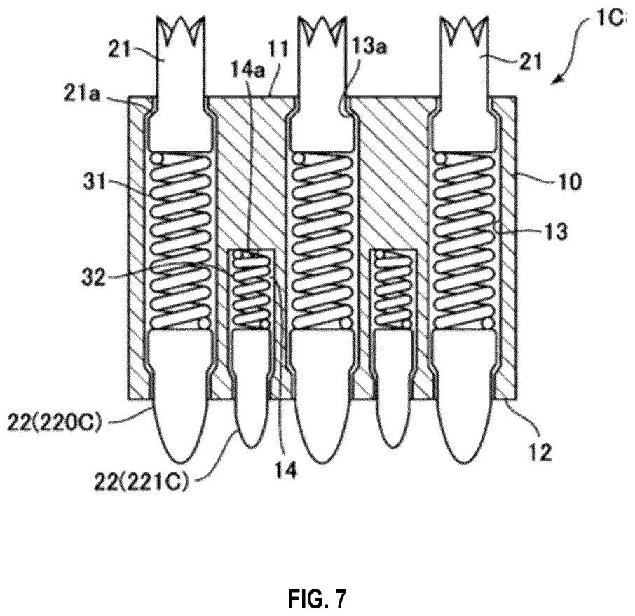

A schematic cross-sectional view of the test probe 1C illustrated in FIG. 6 is illustrated in FIG. 7. In the test probe 1C, a total of three first contact members 21 are all of the same size and shape, while a total of five second contact members 22 utilize two types of contact members. Specifically, among the five second contact members 22, three second contact members 220C are made relatively large, similar to the first contact members 21, while two second contact members 221C disposed between these second contact members 220C are made relatively small. As a result of using such different types of contact members, the number of the second contact members 22 provided adjacent to the second face 12 can be made greater than the number of the first contact members 21 provided adjacent to the first face 11, while ensuring that the surface areas of the first face 11 and second face 12 are of the same size, and, in addition, that the relatively large second contact members 220C provided on the second face 12 have a current flow path of the same size as the first contact members 21 provided on the first face 11.

The first contact members 21 and second contact members 22, which have shoulder portions 21a, are retained inside the support 10 as a result of engaging these shoulder portions 21a with tapers 13a correspondingly provided in the support 10. Although the first contact members 21 and second contact members 22 may be completely secured within the support 10 with the help of these shoulder portions 21a, and the like, all or part thereof may be enabled for resilient expansion and contraction relative to the support 10 in order to facilitate and ensure contact with the test apparatus or the electronic device.

In order to enable resilient expansion and contraction, in the example of FIG. 7, resilient members are provided separately from the first contact members 21 and second contact members 22. For example, the first contact members 21 and the relatively large second contact members 220C are both enabled for resilient expansion and contraction by providing a coil spring 31 along the axial direction “α.” The coil spring 31 is disposed extending through a through-hole provided in the support 10, with one end of the coil spring 31 abutting a first contact member 21 and the other end abutting a second contact member 220C. As a result, both the first contact members 21 and the second contact members 220C can be enabled for resilient expansion and contraction in the axial direction “α.” On the other hand, in the case of the relatively small second contact members 221C, coil springs 32 are provided along the axial direction “α” within bottomed cylindrical spaces 14 provided in the support 10. One end of the coil spring 32 abuts the bottom portion 14a of the cylindrical space 14 and the other end abuts a second contact member 221C, such that only the second contact member 221C is enabled for resilient expansion and contraction.

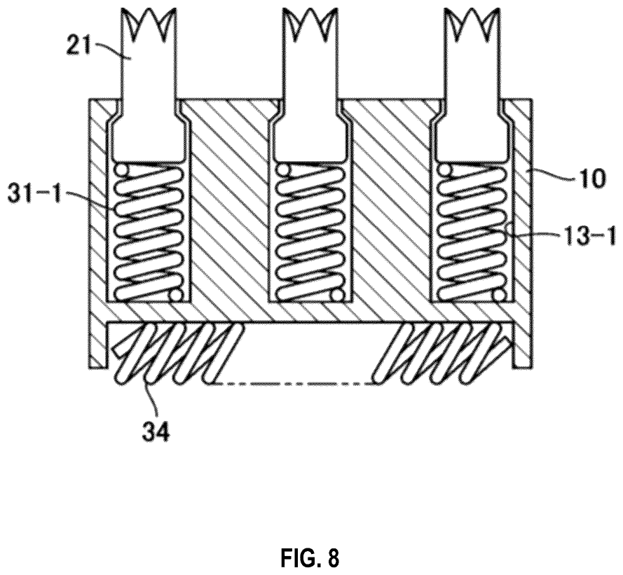

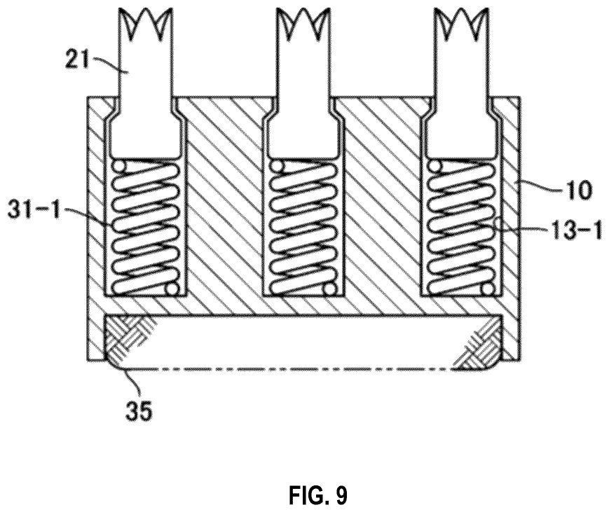

In this manner, instead of providing resilient members, the first contact members themselves or the second contact members themselves may be used as resilient members. An example in which the second contact members themselves are used as resilient members is illustrated in FIG. 8 and FIG. 9. It should be noted that in FIG. 8 and FIG. 9, the same members as in FIG. 7 are given the same reference numerals, or alternatively, “−1” is attached after the same reference numeral. A coil spring 34 is utilized as a resilient member in the example of FIG. 8, while an elastically resilient braid 35 is utilized as a resilient member in FIG. 9. As shown in these drawings, as a result of disposing coil springs 34 or braids 35 serving as second contact members in the horizontal direction, their lateral faces can be brought into contact with the support 10 and the test apparatus. This increases the area of contact between the second contact members and the support 10, etc., and thus increases the path for current flow, making it possible to minimize Joule heating more effectively.

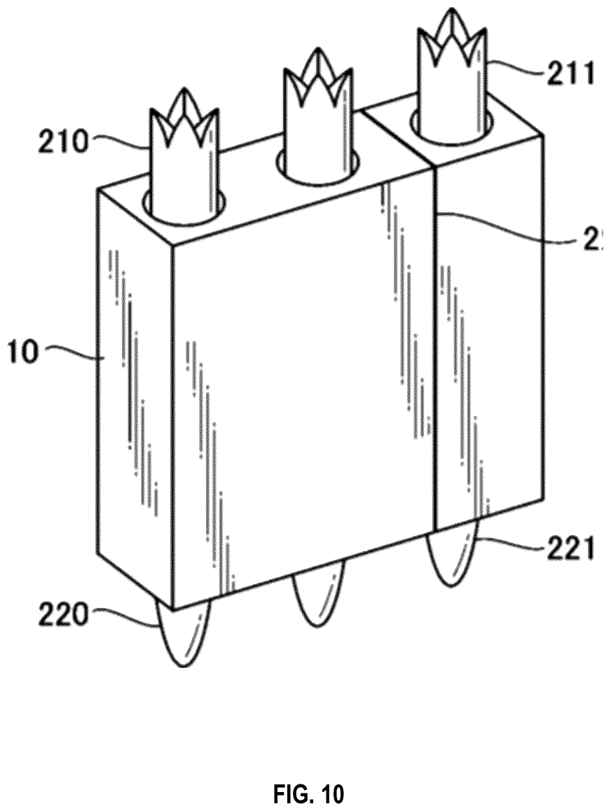

A conceptual view of a test probe with added insulation functionality or capacitor functionality is illustrated in FIG. 10. In order to add insulation functionality or capacitor functionality, an additional layer 2 is provided between first contact members 210 and a first contact member 211 as well as between second contact members 220 and a second contact member 221 so as to separate them from each other. The additional layer 2 may be, for example, an insulating layer, or it may be a capacitor layer. The construction illustrated in FIG. 10 can be used with any type of layer. If an insulating layer (2) is added, separate functionalities can be imparted to the first contact members 210 and the second contact members 220 as well as to the first contact member 211 and the second contact member 221. For example, the former contact members 210, 220 can be used as signal terminals, and the latter contact members 211, 221 can be used as ground terminals, respectively. In addition, if a capacitor layer (2) is added, this additional layer 2 can be used for the reduction of signal noise. For example, it can be used to allow noise that interferes with electronic component testing to escape to the ground circuitry.

It should be noted that while the first contact members 210 and second contact members 220 in the example illustrated in FIG. 10 are provided in a set of two and the first contact member 211 and second contact member 221 are provided in a set of one, it is sufficient to provide at least one first contact member and second contact member respectively on one side and on the opposite side separated by the additional layer, but there are no limitations on their number. For example, the number of the first contact members 210 and second contact members 220 may be varied on one side of the additional layer and, in a similar manner, the number of the first contact members 211 and second contact members 221 may also be varied on the opposite side of the additional layer.

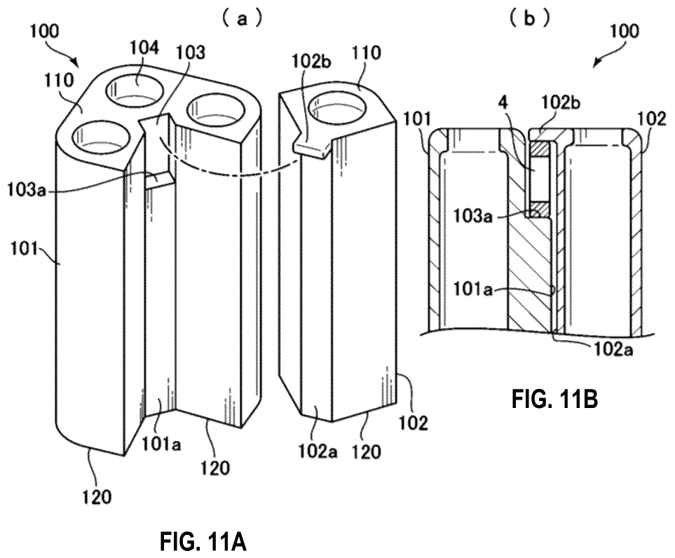

A support 100 used for test probes with an added insulating layer (2) is shown in more detail in FIGS. 11A and 11B. The support 100 is made up of two sections, i.e., a main body portion 101 and a piece 102, which can be joined together. These sections can be joined and held together by coating, etc., the outer periphery thereof with an insulating material (not shown). FIG. 11A shows a perspective view of the main body portion 101 and the piece 102 before they are joined, and FIG. 11B shows a cross-sectional view of the main body portion 101 and the piece 102 after they are joined. Furthermore, FIG. 11B shows a capacitor component 4 disposed inside the support 100.

In the main body portion 101, three test probe elements are arranged in a mutually orthogonal relationship on the first face 110 and second face 120 of the support 10. On the other hand, in the piece 102, only one test probe element is provided on the first face 110 and second face 120 of the support 10. Through-holes 104, into which a set of the first contact members 21 and second contact members 22 can be mounted, are provided in these test probe elements constituting the main body portion 101 and the piece 102 such that there is one through-hole provided per element. When joined together, the main body portion 101 and the piece 102 produce a shape similar to that of the test probe 1B illustrated in FIG. 5. Moreover, a shape produced by coupling the four test probe elements in a rectangular pattern is obtained on the first face 110 and second face 120. However, in order to form a capacitor, the main body portion 101 and the piece 102 are disposed only such that they are never in direct electrical contact even when the main body portion 101 and the piece 102 are joined together, that is, for example, such that one face 101a of the main body portion 101 and one face 102a of the piece 102, while being opposed, have a gap formed therebetween.

In order to form a capacitor, a holding space 103, which holds a capacitor component 4, such as a capacitor or the like, is provided in the main body portion 101. In addition, a cover 102b, which seals the top portion of the holding space 103 once joined together with the main body portion 101, is provided in the piece 102. Once the capacitor component 4 has been placed into a placement portion 103a of the holding space 103 and the top has been sealed by the cover 102b, the capacitor component 4, while being held in the holding space 103, comes into contact with both the main body portion 101 and the cover 102b, thereby capacitively coupling the main body portion 101 and the piece 102.

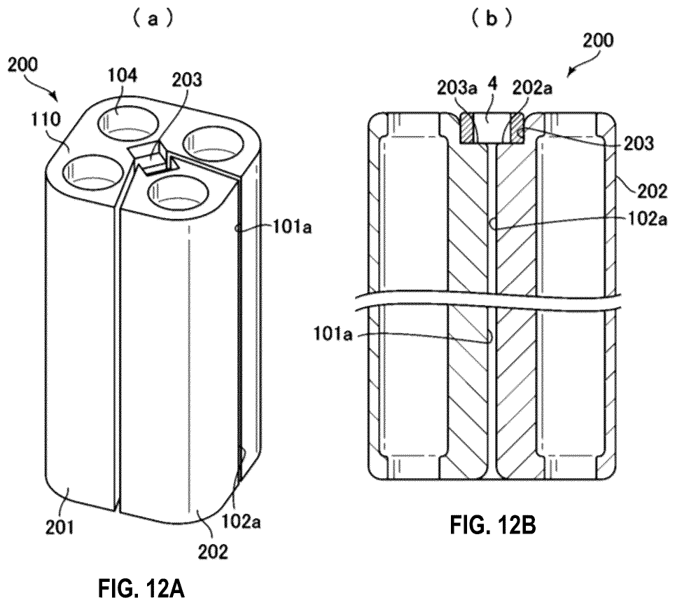

A variation 200 of the support illustrated in FIGS. 11A and 11B is illustrated in FIGS. 12A and 12B. The basic construction of the support 200 is identical to that of the support 100 illustrated in FIGS. 11A and 11B. Components similar to those of FIGS. 11A and 11B are given the same reference numerals as in FIGS. 11A and 11B. In the variation of FIGS. 12A and 12B, the main body portion 201 and the piece 202 cooperate to form a holding space 203. In this holding space 203, the capacitor component 4 is disposed across both a placement portion 203a in the main body portion 201 and a placement portion 202a in the piece 202, thereby capacitively coupling the two portions.

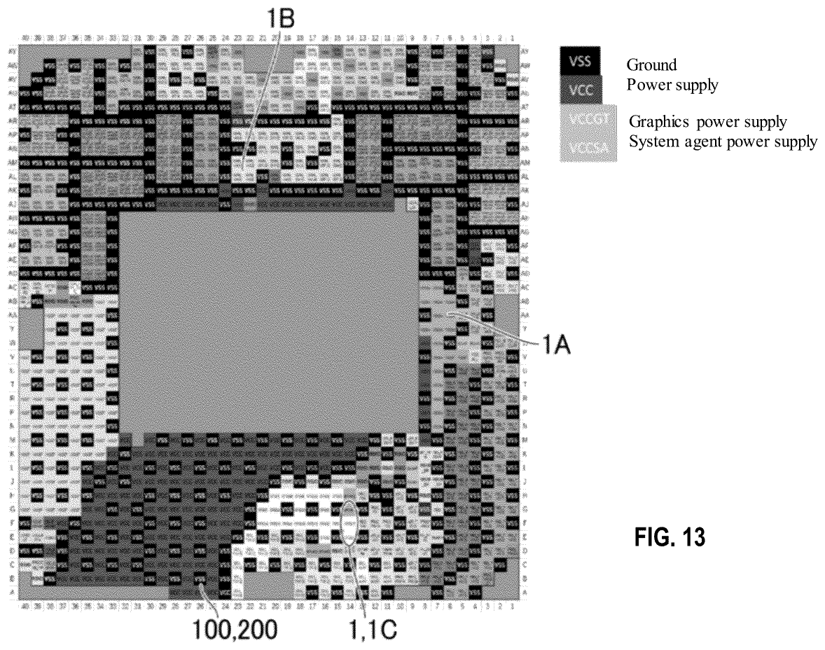

An exemplary method for arranging test probes in the test socket 5 shown in FIGS. 1 and 2 is shown in plan view in FIG. 13. In the test socket 5, the test probes 1 through 1C, 100, and 200 of the various types discussed above can be arranged in a mutually parallel and/or mutually complementary combination on the first face 11 and/or second face 12 of the test probes 1. For example, it is possible to install: test probes 1 having three test probe elements coupled into a row, such as the one illustrated in FIG. 3; test probes 1A having three mutually orthogonal test probe elements, such as the one illustrated in FIG. 4; test probes 1B having four test probe elements coupled in a rectangular pattern, such as the one illustrated in FIG. 5; and test probes 1C having dissimilar numbers of first contact members 21 and second contact members 22, such as the one illustrated in FIG. 6. A desirable arrangement pattern can be formed by combining such various test probes as appropriate. It should be noted that since the test probe elements included in each test probe respectively correspond to typical conventional test probes, the present test probes 1 through 1C, 100, and 200 are essentially capable of being installed a plurality of typical conventional test probes in a single installation operation, which can be expected to simplify test socket manufacturing and lower manufacturing costs. It should be noted that the outer periphery of the support 10 forming part of each test probe may be coated with an insulating material such as a plastic or the like (not shown) in order to prevent electrical connections between pairs of test probes from forming once these test probes are installed in the test socket.

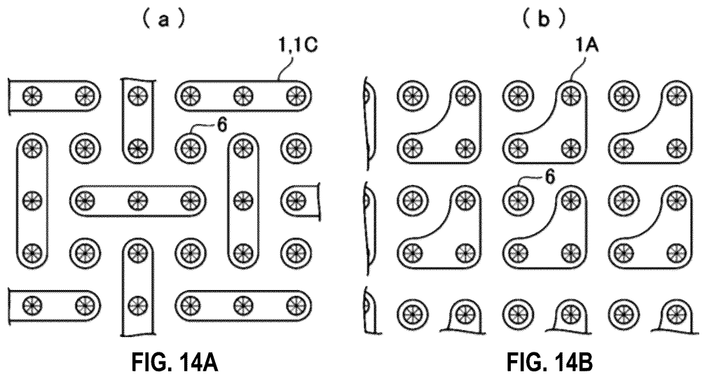

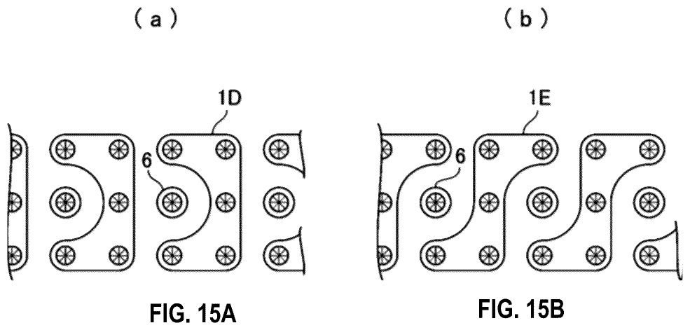

Furthermore, an exemplary method for arranging test probes in the test socket 5 that makes it possible to achieve a reduction in crosstalk is shown in plan view in FIGS. 14A and 14B. This drawing may be considered a magnified view of a portion of FIG. 13. Unlike a typical conventional test probe 6 and, for that matter, the present test probe, a plurality of test probes 1 (1C) in FIGS. 14A and, furthermore, a plurality of test probes 1A in FIGS. 14B are disposed so as to surround the periphery of a test probe 6 made up of a single test probe element on all sides. As a result of such an arrangement, the multiple typical conventional test probes 6 can be separated from one another by the present test probes 1 (1C), etc., which possess a large capacitance, and crosstalk therebetween can be effectively minimized. In such a case, the present test probes 1 (1C) themselves have a large capacitance and, therefore are capable of achieving a reduction in crosstalk by themselves. Furthermore, as illustrated in FIGS. 15A and 15B, variations of the present test probes, namely, test probe 1D, which is obtained by coupling five test probe elements in a substantially C-shaped configuration in the cross-sectional direction, or test probe 1E, which is obtained by coupling elements in a substantially S-shaped configuration, may be disposed so as to surround the periphery of a typical conventional test probe 6. It will be apparent that other, not shown, arrangement methods will readily come to mind. These arrangement methods are, of course, also included in the inventive concepts.

Many modifications or other embodiments of the present invention will come to mind to one skilled in the art to which the invention pertains having the benefit of the teachings presented in the foregoing description, and it will be apparent to those skilled in the art that variations and modifications of the present invention can be made without departing from the scope or spirit of the present invention. Therefore, it is to be understood that the present invention is not to be limited to the specific embodiments disclosed and that modifications and other embodiments are intended to be included within the scope of the appended claims.

### DESCRIPTION OF THE REFERENCE NUMERALS

1 Test probe

2 Additional layer (insulating layer, capacitor layer)

4 Capacitor component

5 Test socket

10 Support

11 First face

12 Second face

13 Through-hole

13a Taper

14 Cylindrical space

21 First contact member

22 Second contact member

31 Coil spring

32 Coil spring

40 Insulating member

51 Base

1. A test probe comprising:
a support of an electrically conductive material having a first face and a second face, first contact members provided adjacent to the first face of the support, and second contact members provided adjacent to the second face of the support,
with at least either one of the first contact members or second contact members being provided as a plurality of members, wherein a plurality of the first contact members and at least one of the second contact members, or a plurality of the second contact members and at least one of the first contact members are electrically connected through the support.

2. The test probe according to claim 1, wherein the first contact members or the second contact members are provided in a manner permitting resilient expansion and contraction relative to the support.

3. The test probe according to claim 2 wherein at least one of the first contact members or at least one of the second contact members is provided in a manner permitting resilient expansion and contraction relative to the support because resilient members are provided separately from the first contact members or the second contact members, or because the first contact members themselves or the second contact members themselves are used as resilient members.

4. The test probe according to claim 3 wherein the resilient members are provided extending through the support between a first contact member and a second contact member, or with one end abutting the support and the other end abutting a first contact member or a second contact member.

5. The test probe according to claim 1 wherein at least one of the plurality of first contact members and at least one other, and at least one of the plurality of second contact members and at least one other are insulated by an insulating layer provided on the support or capacitively coupled by a capacitor layer provided on the support.

6. The test probe according to claim 5 wherein the support has a space in which a capacitor component intended for forming the capacitor layer is held.

7. The test probe according to claim 1 wherein the first contact members are arranged in a row or in a mutually orthogonal manner on the first face, and/or
the second contact members are arranged in a row or in a mutually orthogonal manner on the second face.

8. A test socket, comprising:
a plurality of test probes, each of the plurality of test probes comprising:
a support of an electrically conductive material having a first face and a second face, first contact members provided adjacent to the first face of the support, and second contact members provided adjacent to the second face of the support,
with at least either one of the first contact members or second contact members being provided as a plurality of members, wherein a plurality of the first contact members and at least one of the second contact members, or a plurality of the second contact members and at least one of the first contact members are electrically connected through the support;
wherein the plurality of test probes are arranged on the first face or the second face in a mutually parallel or mutually complementary combination.

9. The test socket according to claim 8 wherein at least one first contact member is provided on the side where the unit to be tested is disposed, and a plurality of the second contact members are provided on the side used for mounting to the test apparatus.

10. The test socket according to claim 8 wherein the plurality of test probes are disposed around the periphery of a test probe consisting of a single test probe element.
